(19) United States
(12) Patent Application Publication
(10) Pub. No.: US 2008/0164572 A1
(43) Pub. Date: Jul. 10, 2008

(54) SEMICONDUCTOR SUBSTRATE AND MANUFACTURING METHOD THEREOF

(75) Inventors: Eiji Toyoda, Niigata (JP); Takeshi Senda, Niigata (JP); Akiko Narita, Niigata (JP); Hiromichi Isogai, Niigata (JP); Koji Izunome, Niigata (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Covalent Materials Corporation, Shinagawa-ku (JP)

(21) Appl. No.: 11/960,061

(22) Filed: Dec. 19, 2007

(30) Foreign Application Priority Data
Dec. 21, 2006 (JP) 2006-344600
Dec. 21, 2006 (JP) 2006-344601
Oct. 25, 2007 (JP) 2007-277181
Oct. 25, 2007 (JP) 2007-277182

(51) Int. Cl. H01L 29/04; H01L 21/304; H01L 21/18

(52) U.S. Cl. 257/616; 257/627; 438/459; 438/460; 257/E21.238; 257/E21.088; 257/E29.004

(57) ABSTRACT

A semiconductor substrate whose surface roughness is reduced by optimizing an inclination (off angle) with respect to a {110} surface of the semiconductor substrate surface and a manufacturing method thereof are provided. The surface of the semiconductor substrate has the inclination (off angle) of 0 degree or more and 0.12 degrees or less, or 5 degrees or more and 11 degrees or less, preferably 6 degrees or more and 9 degrees or less with respect to the {110} surface. The manufacturing method of a semiconductor substrate has a process in which a semiconductor single crystal ingot is sliced at an inclination (off angle) of 5 degrees or more and 11 degrees or less, preferably 6 degrees or more and 9 degrees or less with respect to the {110} surface.

### CROSS-REFERENCE TO RELATED APPLICATION

This application is based upon and claims the benefit of priority from the Japanese Patent Applications No. 2006-344600, filed on Dec. 21, 2006, No. 2006-344601, filed on Dec. 21, 2006, No. 2007-277181, filed on Oct. 25, 2007, and No. 2007-277182, filed on Oct. 25, 2007; the entire contents of which are incorporated herein by reference.

### BACKGROUND OF THE INVENTION

1. Field of the Invention

The present invention relates to a semiconductor substrate and a manufacturing method thereof, and in particular, relates to a semiconductor substrate having a {110} crystal surface orientation and a manufacturing method thereof. The present invention also relates to a semiconductor substrate and a manufacturing method thereof, and in particular, relates to a semiconductor substrate formed by directly bonding semiconductor wafers having different crystal surface orientations and a manufacturing method thereof.

2. Related Art

In the manufacture of current semiconductor products, particularly LSI (Large Scale Integrated circuit) constituted by metal oxide semiconductor field effect transistors (MOSFET), using silicon wafers whose crystal surface orientation is {100} is mainstream. This is mainly because, by forming LSI on the {100} surface, the interface state density can be reduced most effectively in terms of a crystal structure thereof and therefore, reliability and the like of MOSFET can be improved.

It is known that, in a silicon wafer, electrons among carriers of MOSFET have greater mobility in the {100} crystal surface orientation and holes in the {110} crystal surface orientation. That is, the mobility of holes in the {100} crystal surface orientation is ½ to ¼ of that of electrons. On the other hand, the mobility of holes in the <110> direction in the {110} crystal surface orientation is about twice that of holes in the {100} crystal surface orientation. Thus, in LSI of single channel type constituted only by pMOSFET using holes as carriers and CMOS (Complementary Metal Oxide Semiconductor) LSI whose performance is dependent on characteristics of pMOSFET, application of silicon wafers whose crystal surface orientation is {110} instead of {100} can be considered.

Moreover, as described above, while silicon wafers whose surface has the (110) crystal surface orientation are superior in mobility of holes and thus are optimal for pMOSFET, they are not suitable for nMOSFET because of inferior mobility of electrons. Conversely, while silicon wafers whose surface has the (100) crystal surface orientation are superior in mobility of electrons and thus are optimal for nMOSFET, they are not suitable for pMOSFET because of inferior mobility of holes.

Thus, for normal CMOS (Complementary Metal Oxide Semiconductor) LSI, various techniques to create nMOSFET and pMOSFET each in an optimal crystal surface orientation by bonding (gluing together) two wafers to create areas on the silicon wafer surface having different crystal surface orientations have been proposed. That is, for example, techniques enabling high-performance and highly integrated LSI by creating areas of the (100) surface and the (110) surface on the silicon wafer surface and forming nMOSFET on the (100) surface and pMOSFET on the (110) surface have been proposed. As one such technique, a method (ATR method: Amorphization/Templated Recrystallization method) of creating areas on the silicon wafer surface having different crystal surface orientations, by which silicon wafers having different crystal surface orientations on their surfaces are directly bonded and then ions of silicon or the like are injected to amorphize a certain region of the upper silicon single crystal layer up to the bonding interface with the lower layer and the amorphized layer is annealed for recrystallization based on crystal orientation information of the lower layer, as disclosed for example in U.S. Pat. No. 7,060,585 B1.

Most carriers flowing through a channel of a transistor are considered to flow through a channel top surface, that is, an area of the depth of about 3 nm from the channel surface. Factors that have been known to degrade mobility of such carriers include channel impurities, phonons, and carrier scattering due to surface roughness of the channel. As a technique to inhibit scattering due to channel impurities, for example, a technique to decrease the concentration of impurities by forming a transistor in the SOI (Silicon On Insulator) layer to enable complete depletion of the channel has been proposed. In order to inhibit phonon scattering, it is effective to operate transistors at a lower temperature to inhibit lattice vibration of semiconductor. Then, as a means for improving surface roughness, a technique to form a flat surface by annealing the surface of a silicon wafer in an argon gas atmosphere to reconstitute silicon atoms at the wafer surface has been disclosed (JP-A H08-264401(KOKAI)).

### SUMMARY OF THE INVENTION

A semiconductor substrate in one aspect of the present invention has an inclination (off angle) of 0 degree or more and 0.12 degrees or less, or 5 degrees or more and 11 degrees or less with respect to the {110} surface from the surface thereof.

Also, a manufacturing method of a semiconductor substrate in one aspect of the present invention has a process in which a semiconductor single crystal ingot is sliced at an inclination (off angle) of 0 degree or more and 0.12 degrees or less, or 5 degrees or more and 11 degrees or less with respect to the {110} surface.

Also, a semiconductor substrate in another aspect of the present invention is a semiconductor substrate formed by a first semiconductor wafer and a second semiconductor wafer being directly bonded. Then, the surface of one of the first semiconductor wafer and second semiconductor wafer substantially has the {100} surface orientation. Then, the surface of the other semiconductor wafer has an inclination (off angle) of 0 degree or more and 0.12 degrees or less, or 5 degrees or more and 11 degrees or less with respect to the {110} surface.

Also, a manufacturing method of a semiconductor substrate in another aspect of the present invention is a manufacturing method of a semiconductor substrate having a process in which a first semiconductor wafer and a second semiconductor wafer are bonded together. Then, the manufacturing method of a semiconductor substrate has a process in which one of the first semiconductor wafer and second semiconductor wafer is prepared by slicing a semiconductor single crystal ingot substantially horizontally with respect to the {100} surface and a process in which the other semiconductor wafer is prepared by slicing the semiconductor single crystal ingot at an inclination (off angle) of 0 degree or more and 0.12 degrees or less, or 5 degrees or more and 11 degrees or less with respect to the {110} surface.

### BRIEF DESCRIPTION OF THE DRAWINGS

FIG. 1 is a schematic diagram of a semiconductor substrate in an embodiment.

FIG. 2 is a schematic diagram for illustrating an inclination and an azimuth of the semiconductor substrate in the embodiment.

FIG. 3 is a diagram showing a relationship between the inclination and surface roughness after surface heat treatment according to the example.

FIG. 4 is a diagram showing the relationship between the inclination and surface roughness after surface heat treatment according to another example.

FIG. 5 is a schematic diagram of a semiconductor substrate in the other embodiment.

FIG. 6 is a diagram showing a manufacturing process flow of the semiconductor substrate in the other embodiment.

### DETAILED DESCRIPTION OF THE EMBODIMENTS

As the scaling down of LSI advances and the channel length of a transistor shrinks below 50 nm, the area of a channel decreases and thus, the number of impurities inside the channel drops to one or less. Therefore, scattering of carriers by impurities will no longer be a dominant factor of degraded mobility of carriers. Moreover, phonon scattering is determined by the operating temperature of semiconductor material and transistors.

Thus, in order to further enhance carrier mobility and improve characteristics of scaled down transistors, the inventors thought that it is important to inhibit scattering of carriers particularly by controlling and planarizing surface roughness of channels. Then, the inventors conducted a study by focusing on the possibility that surface roughness of a semiconductor depends on the inclination (off angle) of the surface of a semiconductor substrate with respect to the {110} surface.

Embodiments of a semiconductor substrate according to the present embodiment and a manufacturing method thereof will be described referring to attached drawings. Though the embodiments will be described by taking as an example a case in which a silicon wafer is used as a semiconductor substrate, the present invention is not necessarily limited to the manufacturing method of a semiconductor substrate using silicon wafers. Moreover, herein the notation of the {100} surface and {110} surface will be used as a notation representing crystallographically equivalent surfaces to the (100) surface and (110) surface respectively. Then, the notation of the <100> direction and <110> direction will be used as a notation representing crystallographically equivalent directions to the [100] direction and [110] direction respectively.

### First Embodiment

A semiconductor substrate in a first embodiment of the present invention is a silicon wafer whose surface has an inclination (off angle) of 0 degree or more and 0.12 degrees or less, or 5 degrees or more and 11 degrees or less with respect to the {110} surface. When a silicon wafer whose surface has the {110} surface is used to improve mobility of holes, which are carriers of pMOSFET, the inclination (off angle) has generally been set to 0 degree. This is because when the Czochralski method (CZ method), which is the most common method of silicon wafer mass production, is used, it is appropriate to set the inclination to 0 degree to efficiently cut out the large silicon wafer from a silicon single crystal ingot having the {110} orientation.

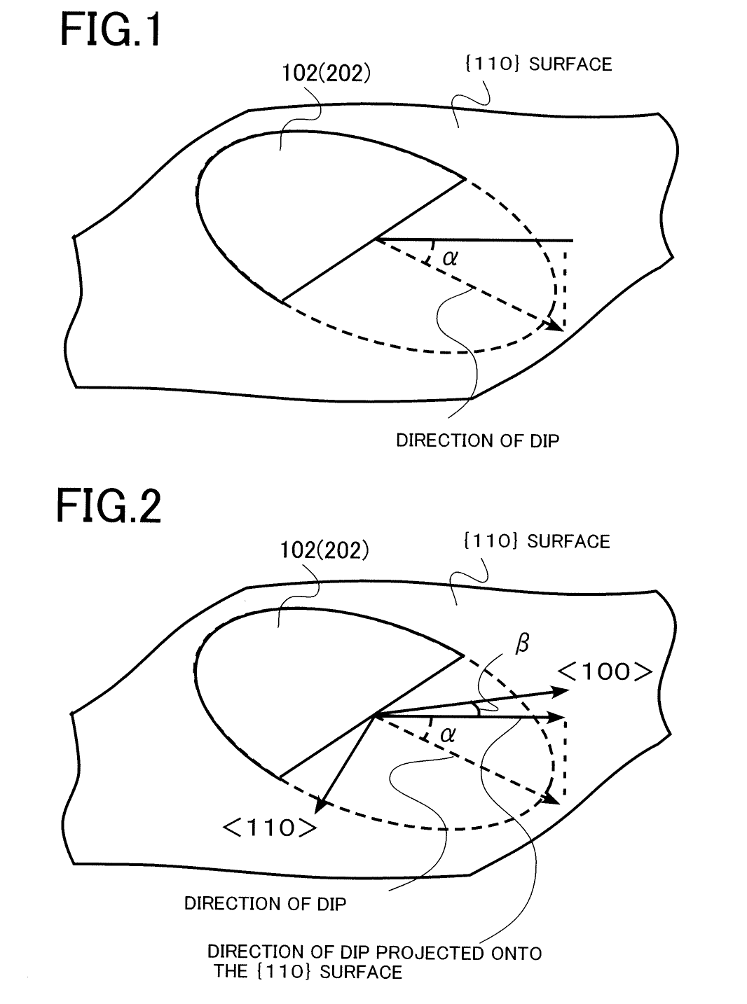

FIG. 1 shows a schematic diagram of a semiconductor substrate in the present embodiment. As shown in the figure, the inclination (off angle) of the surface of a silicon wafer 102 with respect to the {110} surface, that is, an angle α between the direction of dip of the silicon wafer with respect to the {110} surface and the {110} surface is 0 degree or more and 0.12 degrees or less, or 5 degrees or more and 11 degrees or less.

According to a semiconductor substrate in the present embodiment, a surface roughness is improved after surface planarization heat treatment performed in a later wafer manufacturing process or semiconductor device manufacturing process. Therefore, high performance of MOSFET formed on the semiconductor substrate can be achieved. This is because, with reduced surface roughness, degradation of carrier mobility caused by scattering can be prevented. Further, dielectric strength/reliability of gate dielectric films can be improved by reduced roughness of the interface between the dielectric films and semiconductor interface.

Incidentally, the surface planarization heat treatment here is heat treatment for planarizing the surface of a semiconductor by reconstituting atoms at the surface of the semiconductor substrate. For example, heat treatment provided in an atmosphere of a reducing gas, an inert gas, or a mixed gas of a reducing gas and an inert gas at a temperature of 900° C. or higher and 1350° C. or lower for a time of 30 minutes or more and 5 hours or less.

In the present embodiment, it is preferable that the inclination of the surface of a semiconductor substrate with respect to the {110} surface be 6 degrees or more and 9 degrees or less. This is because a further reduction effect of surface roughness can be gained by limiting the inclination to this range.

Moreover, in the present embodiment, the azimuth of the direction of dip with respect to the {110} surface is not necessarily limited. Here, the azimuth is an angle, like P shown in FIG. 2, between a direction obtained by projecting the direction of dip of a silicon wafer onto the {110} surface and the <100> direction on the same {110} surface.

Incidentally, it is preferable that the azimuth when the direction of dip with respect to the {110} surface is projected onto the {110} surface be in a range of ±26 degrees with respect to the <100> direction. That is, the azimuth β shown in FIG. 2 is preferably in the range of 0 degree±26 degrees. This is because, if this range is exceeded and heat treatment of about 1200° C. is provided in an atmosphere of an inert gas after surface polishing, RMS (Root Mean Square), which is an index of surface roughness of silicon wafers, increases and thus dielectric film breakdown strength of oxide films and the like formed on the surface and reliability of dielectric films could be degraded.

Moreover, it is preferable that the azimuth on the {110} surface of the direction of dip with respect to the {110} surface be ±2 degrees with respect to the <100> direction. This is because it is expected for such a silicon wafer to realize desired RMS for device formation also after heat treatment.

Also, in view of enhancement of transistor mobility, it is preferable that the azimuth when the direction of dip with respect to the {110} surface of the surface of a silicon wafer is projected onto the {110} surface be in the range of ±5 degrees with respect to the <100> direction, that is, the azimuth β shown in FIG. 2 be in the range of 0 degree±5 degrees. This is because a benefit of improved hole mobility will be received by pMOSFET formed on a silicon wafer by setting the azimuth β in the range of 0 degree±5 degrees. That is, the greatest hole mobility is obtained in the <110> direction and the movement direction of holes in pMOSFET can always be made parallel to the <110> direction by tilting the silicon wafer surface to the <100> direction, which is perpendicular to the <110> direction. Therefore, mobility degradation caused by the fact that the movement direction of holes in the channel and the <110> direction are oblique will not occur. In addition, it becomes possible to make the movement direction of holes in pMOSFET always parallel to the <110> direction even if the inclination when slicing silicon wafers from an ingot varies. Therefore, there is an advantage that variations in hole mobility originating from variations in inclination can be inhibited.

Next, a manufacturing method of a semiconductor substrate according to the present embodiment of the present invention will be described. The manufacturing method of a semiconductor substrate according to the present embodiment includes a process in which a semiconductor single crystal ingot is sliced at an inclination (off angle) of 0 degree or more and 0.12 degrees or less, or 5 degrees or more and 11 degrees or less with respect to the {110} surface.

More specifically, first a semiconductor single crystal ingot in the crystal orientation {110} produced by the Czochralski method (CZ method) is sliced at an inclination (off angle) of 0 degree or more and 0.12 degrees or less, or 5 degrees or more and 11 degrees or less, preferably 6 degrees or more and 9 degrees or less with respect to the {110} surface. This is because, as described above, surface roughness after heat treatment of semiconductor substrates to be manufactured is reduced by selecting the inclination of 0 degree or more and 0.12 degrees or less, or 5 degrees or more and 11 degrees or less, and the surface roughness is further reduced by selecting the inclination of 6 degrees or more and 9 degrees or less. When the inclination is in the range of 6 degrees or more and 9 degrees or less, dependence of surface roughness after heat treatment on the inclination is small and stable. Thus, there is an advantage that wafer surface planarization after heat treatment is stabile even if the slicing angle varies in a process of slicing.

Here, when growing a single crystal by the CZ method, as is generally practiced, the {110} surface of a seed crystal may be matched to the horizontal plane for growing the single crystal. However, it is preferable that a single crystal be grown by tilting the {110} surface of the seed crystal in advance by 5 degrees or more and 11 degrees or less, preferably 6 degrees or more and 9 degrees or less, for example, 8 degrees with respect to the horizontal plane. This is because, by growing the silicon single crystal ingot after the seed crystal being tilted in advance by an angle corresponding to a desired inclination, the silicon single crystal ingot will be sliced almost perpendicularly to the length direction of the silicon single crystal ingot in the slicing process. Therefore, slicing work will be made easier. Moreover, the volume of single crystal in the silicon single crystal ingot that will be unusable as a silicon wafer and thus discarded can be reduced by slicing the silicon single crystal ingot almost perpendicularly, realizing reduced manufacturing costs.

In the present embodiment, the azimuth of the direction of dip with respect to the {110} surface is not necessarily limited in a process of slicing a silicon single crystal ingot.

However, it is preferable to slice in such a way that the azimuth on the {100} surface of the direction of dip with respect to the {110} surface is in the range of +26 degrees with respect to the <100> direction. That is, it is preferable that a silicon single crystal ingot be sliced in such a way that the azimuth β shown in FIG. 2 is in the range of 0 degree±26 degrees. This is because, as described above, if this range is exceeded and heat treatment of about 1200° C. is provided in an atmosphere of an inert gas after surface polishing, RMS (Root Mean Square), which is an index of surface roughness of silicon wafers, increases and thus dielectric film breakdown strength of oxide films and the like formed on the surface and reliability of dielectric films could be degraded.

Moreover, it is preferable that a silicon single crystal ingot be sliced in such a way that the azimuth on the {110} surface of the direction of dip with respect to the {110} surface be ±2 degrees with respect to the <100> direction. This is because, as described above, it is expected for a wafer sliced in the range to realize desired RMS for device formation also after heat treatment.

Incidentally, the desirable RMS value for device formation cannot be necessarily determined uniquely in view of demanded device performance. However, it is generally preferable that the RMS value of about 0.2 nm or less be realized. High device performance can be realized by forming a device using a semiconductor substrate manufactured by the manufacturing method in the present embodiment whose RMS value is 0.2 nm or less.

Also, in view of enhancement of transistor mobility, it is preferable that a silicon single crystal ingot be sliced in such a way that the azimuth on the {110} surface of the direction of dip with respect to the {110} surface of the surface of a silicon wafer to be cut out be in the range of ±5 degrees with respect to the <100> direction, that is, the azimuth β shown in FIG. 2 be in the range of 0 degree±5 degrees. This is because, as described above, a benefit of improved hole mobility will be received by pMOSFET formed on the silicon wafer of a semiconductor substrate manufactured in this manner. In addition, as described above, there is an advantage that a semiconductor substrate manufactured in this manner has no variations in hole mobility originating from variations in inclination when cutting out silicon wafers from an ingot by slicing.

Next, mirror polishing is performed while maintaining the surface orientation to remove roughness on the silicon wafer surface generated in the process of slicing. Surface roughness after surface planarization heat treatment performed in a later wafer manufacturing process or semiconductor device manufacturing process will be improved as described above. Therefore, silicon wafers having an operation effect of higher performance of MOSFET formed on the silicon wafers can be manufactured.

Incidentally, in the manufacturing method in the present embodiment, planarization heat treatment may be provided in an atmosphere of a reducing gas, an inert gas, or a mixed gas of a reducing gas and an inert gas at a temperature of 900° C. or higher and 1350° C. or lower for a time of 30 minutes or more and 5 hours or less after mirror polishing. Here, a reducing gas, an inert gas, or a mixed gas of a reducing gas and an inert gas is used as an atmosphere for heat treatment because, if any other gas is used, atoms at the silicon wafer surface will not be reconstituted, making planarization of the silicon wafer surface difficult. Particularly, if an oxidizing gas mingles, reconstitution of atoms at the silicon surface becomes extremely difficult due to oxidization of the silicon wafer surface.

Also, heat treatment is provided at a temperature of 900° C. or higher and 1350° C. or lower for a time of 30 minutes or more and 5 hours or less because, if heat treatment is provided in the range of lower temperature or shorter time, it becomes difficult to realize planarization by heat treatment. If, on the other hand, heat treatment is provided in the range of higher temperature or longer time, metallic contamination of silicon wafers increases. Further, if heat treatment is provided in the range of higher temperature or longer time, the probability of occurrence of a slip to silicon wafers increases and also the life of members of a heat treatment apparatus decreases, making heat treatment unrealistic.

Adding heat treatment for planarization in a silicon wafer manufacturing stage, as described above, makes additional planarization heat treatment unnecessary in the semiconductor device manufacturing process. Therefore, it becomes possible to form dielectric films for MOSFET and capacitors having excellent characteristics on the silicon wafers without providing planarization heat treatment.

Here, the silicon single crystal ingot to be used need not be necessarily a single crystal grown by the Czochralski method (CZ method) and, for example, may be a single crystal grown by the floating zone method (FZ method). Also, the heat treatment apparatus used by the manufacturing method in the present embodiment is not particularly limited and, for example, a batch-type vertical heat treating furnace or a single wafer RTP (Rapid Thermal Processing) apparatus may be used.

The present embodiment has been described by assuming that the semiconductor substrate is made of silicon (Si), but a similar operation effect can be gained by SixGe1−x (0≦x<1), which has a crystal structure basically similar to that of silicon. In addition, by using SixGe1−x (0≦x<1) as a material, mobility of carriers, particularly holes, which are carriers of pMOSFET, is enhanced. Thus, an effect that LSI formed on a semiconductor substrate achieves ever higher performance is gained.

Concrete examples of the present invention will be described below, but the present invention is not limited by these examples.

### Example 1

A silicon single crystal ingot measuring 8 inches and having the crystal surface orientation (110) was fabricated by the Czochralski method (CZ method). The silicon single crystal ingot was grown by keeping the (110) surface of the seed crystal level during pulling up of the ingot. The ingot is a p-type silicon single crystal with boron as impurities and having resistivity of 9 to 22 Ω·cm. The silicon single crystal ingot was sliced in such a way that the azimuth of the surface of a silicon wafer to be cut out on the (110) surface in the direction of dip with respect to the (110) surface matches the <100> direction, that is, the azimuth β shown in FIG. 2 is 0 degree.

Also, by slicing the silicon single crystal ingot aiming at the inclination (off angle) in increments of 1 degree from 0 degree to 12 degrees with respect to the (110) surface, silicon wafers with different inclinations (off angles) indicated by the angle α in FIG. 2 were prepared. Next, silicon wafers obtained by slicing were cleansed by hydrogen fluoride-nitric acid and then mirror-polished. Subsequently, the silicon wafers were heat-treated for planarization by the batch-type vertical heat treating furnace under conditions of a hydrogen gas atmosphere, 1200° C., and 1 hour.

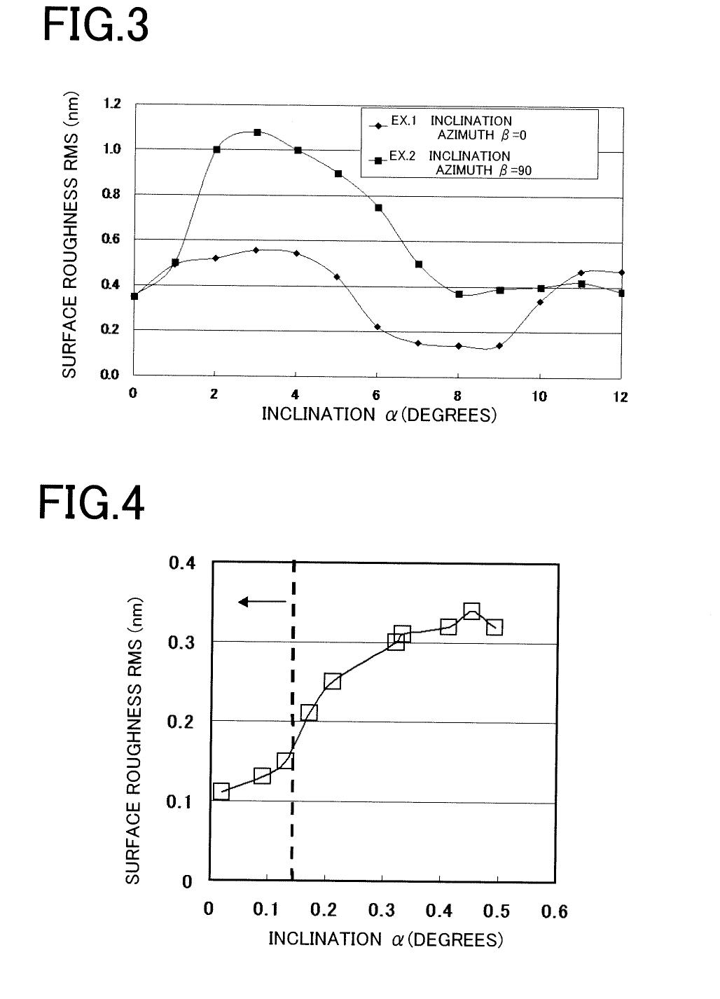

Surface roughness of the above silicon wafers was evaluated in arbitrary 10 μm×10 μm measuring areas by means of AFM (Nano Scope IIIa). RMS (Root Mean Square) was used as an index of surface roughness. Results are shown in FIG. 3.

As is evident from FIG. 3, the surface roughness (RMS value) in the range where the inclination (off angle) α is 5 degrees or more and 11 degrees or less is satisfactory with 0.2 nm or less, which is equal to or less than the surface roughness in the vicinity of 0 degree. Further, when the inclination (off angle) α is 6 degrees or more and 9 degrees or less, the surface roughness is more satisfactory with stabilizing surface roughness of about half that in the vicinity of 0 degree or less. Incidentally, measurement of the silicon wafer sliced by aiming at the 0 degree using a high-performance X-ray diffractometer showed that the silicon wafer has an inclination of 0.45 degrees.

### Example 2

A silicon single crystal ingot measuring 8 inches and having the crystal surface orientation (110) was fabricated by the Czochralski method (CZ method). The silicon single crystal ingot was grown by keeping the (110) surface of the seed crystal level during pulling up of the ingot. The ingot is a p-type silicon single crystal with boron as impurities and having resistivity of 9 to 22 Ω·cm. The silicon single crystal ingot was sliced in such a way that the azimuth of the surface of a silicon wafer to be cut out on the (110) surface in the direction of dip with respect to the (110) surface matches the <110> direction, that is, the azimuth β shown in FIG. 2 is 90 degrees.

Also, by slicing the silicon single crystal ingot aiming at the inclination (off angle) in increments of 1 degree from 0 degree to 12 degrees with respect to the (110) surface for each azimuth, silicon wafers with different inclinations (off angles) indicated by the angle α in FIG. 2 were prepared. Next, silicon wafers obtained by slicing were cleansed by hydrogen fluoride-nitric acid and then mirror-polished. Subsequently, the silicon wafers were heat-treated for planarization by the batch-type vertical heat treating furnace under conditions of a hydrogen gas atmosphere, 1200° C., and 1 hour.

Surface roughness of the above silicon wafers was evaluated in arbitrary 10 μm×10 μm measuring areas by means of AFM (Nano Scope IIIa). RMS (Root Mean Square) was used as an index of surface roughness. Also for comparison, wafers to which no heat treatment had been provided were also measured. Results are shown in FIG. 3. RMS before providing heat treatment is about 0.18 nm and, as is evident from FIG. 3, RMS on the (110) surface tends to deteriorate by providing heat treatment. When the orientation in the direction of dip is <110>, when compared with <100>, RMS is greater, which is not desirable for ensuring yields of semiconductor devices such as LSI.

If the orientation in the direction of dip is changed from <100> to <110>, in view of nature of continuity of crystals and the like, RMS is also expected to deteriorate continuously. Therefore, it is expected that an RMS value desirable for device formation can be realized also after heat treatment if the range of the azimuth on the {110} surface of the direction of dip with respect to the {110} surface is ±26 degrees with respect to the <100> direction.

### Example 3

A silicon single crystal ingot measuring 8 inches and having the crystal surface orientation (110) was fabricated by the Czochralski method (CZ method). The ingot is a p-type silicon single crystal with boron as impurities and having resistivity of 9 to 22 Ω·cm. The silicon single crystal ingot was sliced in such a way that the azimuth on the (110) surface of the direction of dip with respect to the (110) surface of the surface of a silicon wafer to be cut out matches the <100> direction, that is, the azimuth β shown in FIG. 2 is 0 degree. Also by slicing the silicon single crystal ingot in such a way that the inclination (off angle) with respect to the (110) surface becomes 0 to 0.5 degrees, silicon wafers with different inclinations (off angles) indicated by the angle α in FIG. 2. Next, silicon wafers obtained by slicing were cleansed by hydrogen fluoride-nitric acid and then mirror-polished. Subsequently, the silicon wafers were heat-treated for planarization by the batch-type vertical heat treating furnace under conditions of a hydrogen gas atmosphere, 1200° C., and 1 hour.

Surface roughness of the above silicon wafers was evaluated in arbitrary 10 μm×10 μm measuring areas by means of AFM (Nano Scope IIIa). RMS (Root Mean Square) was used as an index of surface roughness. Results are shown in FIG. 4. As is evident from FIG. 4, the surface roughness is satisfactory with the RMS value of 0.2 nm or less when the inclination (off angle) α is in the range of 0.0 degree or more and 0.12 degrees or less.

### Second Embodiment

A semiconductor substrate in the present embodiment is a semiconductor substrate formed by a first silicon wafer and a second silicon wafer directly being bonded, and the surface of the first silicon wafer substantially has the {100} surface orientation and the surface of the second silicon wafer has an inclination (off angle) of 0 degree or more and 0.12 degrees or less, or 5 degrees or more and 11 degrees or less with respect to the {110} surface. Moreover, in the present embodiment, the first silicon wafer is a base wafer to be a substrate side and the second silicon wafer is a bond wafer to be an active layer side.

Here, direct bonding is a state in which there is no thick silicon oxide film at a bonding interface of two wafers, that is, no continuous silicon oxide film is formed. The surface substantially having the {100} surface orientation concretely means that the wafer surface has the range of 0 degree or more and 5 degrees or less with respect to the {100} surface.

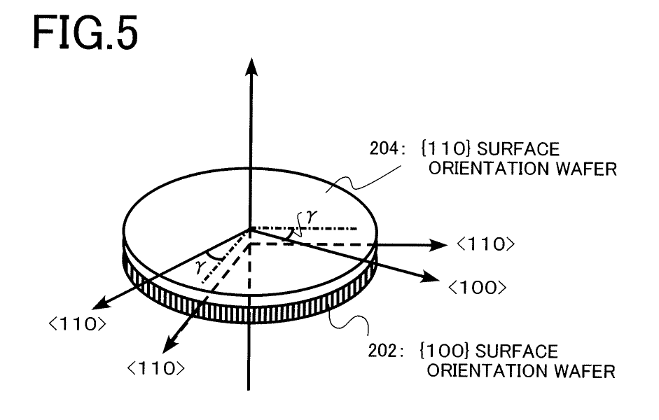

FIG. 5 shows a schematic diagram of a semiconductor substrate in the present embodiment. As shown in the figure, a {100} surface orientation wafer 202, which is the first silicon wafer, acting as a base wafer and a {110} surface orientation wafer 204, which is the second silicon wafer, acting as a bond wafer are bonded directly without a thick oxide film. Moreover, in the present embodiment, the {110} surface orientation wafer 204 is made thinner than the {100} surface orientation wafer 102 due to necessity to cause an area having different surface orientations on the surface of the semiconductor substrate to appear using the ATR method or the like later. More specifically, the thickness may be on the order of 100 nm to 1 μm.

As described above, in the present embodiment, as shown in FIG. 1, the inclination (off angle) of the surface of the silicon wafer 202 with respect to the {110} surface, that is, the angle α between the direction of dip of the silicon wafer with respect to the {110} surface and the {110} surface is 0 degree or more and 0.12 degrees or less, or 5 degrees or more and 11 degrees or less.

Incidentally, an angle (rotation angle: the angle γ in FIG. 5) between the <110> direction of the silicon wafer surface having the {100} surface orientation in FIG. 5 and the <110> direction of the silicon wafer surface having the {110} surface orientation is not particularly limited. However, y=0 degree is preferable in terms of the CMOS circuit design for drawing an advantage of an increase in mobility. By setting γ=0 degree, in the case channels of pMOSFET and nMOSFET of LSI are arranged in parallel or perpendicular directions, carrier mobility of both can be maximized. Therefore, LSI arrangement is made easier and design efficiency is improved.

According to a semiconductor substrate in the present embodiment, an effect of improved planarization at a bonding interface after heat treatment performed in a later wafer manufacturing process or semiconductor device manufacturing process and efficient inhibition of misfit dislocation involved in lattice misfit and an increase in interface state density is gained. Therefore, characteristics of semiconductor devices formed on the semiconductor substrate surface are enhanced. More specifically, for example, lattice defects originating from misfit dislocation can be inhibited from appearing in a recrystallization area during recrystallization by the ATM method. Moreover, by reducing the interface state density, for example, a leak current in a pn junction crossing the bonding interface can be reduced.

Also, an operation effect of improved surface roughness after surface planarization heat treatment performed in the later wafer manufacturing process or semiconductor device manufacturing process and higher performance of MOSFET formed on the semiconductor substrate is gained. This is because, with reduced surface roughness, degradation of carrier mobility caused by scattering can be prevented. Further, dielectric strength/reliability of gate dielectric films can be improved not only by higher performance of MOSFET, but also by reduced roughness of the interface between the dielectric films and semiconductor interface.

Improvement of planarization at the bonding interface after heat treatment becomes more pronounced as the base wafer 204 becomes thinner. This is because out-diffusion of oxygen in an interfacial silicon oxide film is promoted as the base wafer 204 becomes thinner, making rearrangement of silicon at the interface more likely. Therefore, it is preferable that the thickness of the second wafer, which is a base wafer, be 1 μm or less, if possible, 200 nm or less. The surface planarization heat treatment here is heat treatment for planarizing the surface of a semiconductor by reconstituting atoms at the surface of a semiconductor substrate and, for example, heat treatment performed in an atmosphere of a reducing gas, an inert gas, or a mixed gas of a reducing gas and an inert gas at a temperature of 900° C. or higher and 1350° C. or lower for a time of 30 minutes or more and 5 hours or less.

Also in the present embodiment, it is preferable that the inclination of the surface of a semiconductor substrate with respect to the {110} surface be 6 degrees or more and 9 degrees or less. This is because still more effects of improved interface planarization and reduced surface roughness after heat treatment can be gained by limiting the inclination to this range. Moreover, in the present embodiment, the azimuth in the direction of dip with respect to the {110} surface is not necessarily limited. Here, the azimuth is an angle, like β shown in FIG. 2, between the direction obtained by projecting the direction of dip of a silicon wafer onto the {110} surface and the <100> direction on the same {110} surface.

However, it is preferable that the azimuth when the direction of dip of the surface of a silicon wafer with respect to the {110} surface is projected onto the {110} surface be in the range of +5 degrees with respect to the <100> direction, that is, the azimuth β shown in FIG. 2 is preferably in the range of 0 degree±5 degrees. This is because a benefit of improved hole mobility will be received by pMOSFET formed on the silicon wafer by setting the azimuth β in the range of 0 degree±5 degrees. That is, the greatest hole mobility is obtained in the <110> direction and the hole movement direction of pMOSFET can always be made parallel to the <110> direction by tilting the silicon wafer surface to the <100> direction, which is perpendicular to the <110> direction. Therefore, mobility degradation caused by the fact that the movement direction of holes in the channel and the <110> direction are oblique will not occur. In addition, it becomes possible to make the hole movement direction of pMOSFET always parallel to the <110> direction even if the inclination when slicing silicon wafers from an ingot varies. Therefore, there is an advantage that variations in mobility originating from variations in inclination can be inhibited.

### Third Embodiment

In a semiconductor substrate in the present embodiment, like the second embodiment, the surface of the first silicon wafer in general has the {100} surface orientation and the surface of the second silicon wafer has an inclination (off angle) of 0 degree or more and 0.12 degrees or less, or 5 degrees or more and 11 degrees or less with respect to the {110} surface. Moreover, except that the first silicon wafer is a bond wafer to be an active layer side and the second silicon wafer is a base wafer to be a substrate side, the present embodiment is like the first embodiment and thus, a repetitional description thereof is omitted.

In the present embodiment, the surface forming a semiconductor device has the {100} surface orientation, but when the ATM method is applied, a surface appears on this surface having the inclination (off angle) of 0 degree or more and 0.12 degrees or less, or 5 degrees or more and 11 degrees or less with respect to the {110} surface. Therefore, in the present embodiment, like the second embodiment, an operation effect of improved surface roughness and higher performance of MOSFET formed on the semiconductor substrate is gained after applying the ATR method and providing heat treatment.

### Fourth Embodiment

Next, an embodiment of a manufacturing method of a semiconductor substrate of the present invention will be described. The manufacturing method of a semiconductor substrate in the present embodiment is a manufacturing method of a semiconductor substrate having a process in which a first silicon wafer and a second silicon wafer are bonded together that includes a process in which the first semiconductor wafer is prepared by slicing a semiconductor single crystal ingot substantially in parallel to the {100} surface and a process in which the second semiconductor wafer is prepared by slicing the semiconductor single crystal ingot at an inclination (off angle) of 0 degree or more and 0.12 degrees or less, or 5 degrees or more and 11 degrees or less with respect to the {110} surface. Then, after the process of bonding together, the manufacturing method of a semiconductor substrate includes a process of making the second silicon wafer thinner and a process of heat-treating the bonded silicon wafer in an atmosphere of a reducing gas, an inert gas, or a mixed gas of a reducing gas and an inert gas at a temperature of 900° C. or higher and 1350° C. or lower for a time of 30 minutes or more and 5 hours or less.

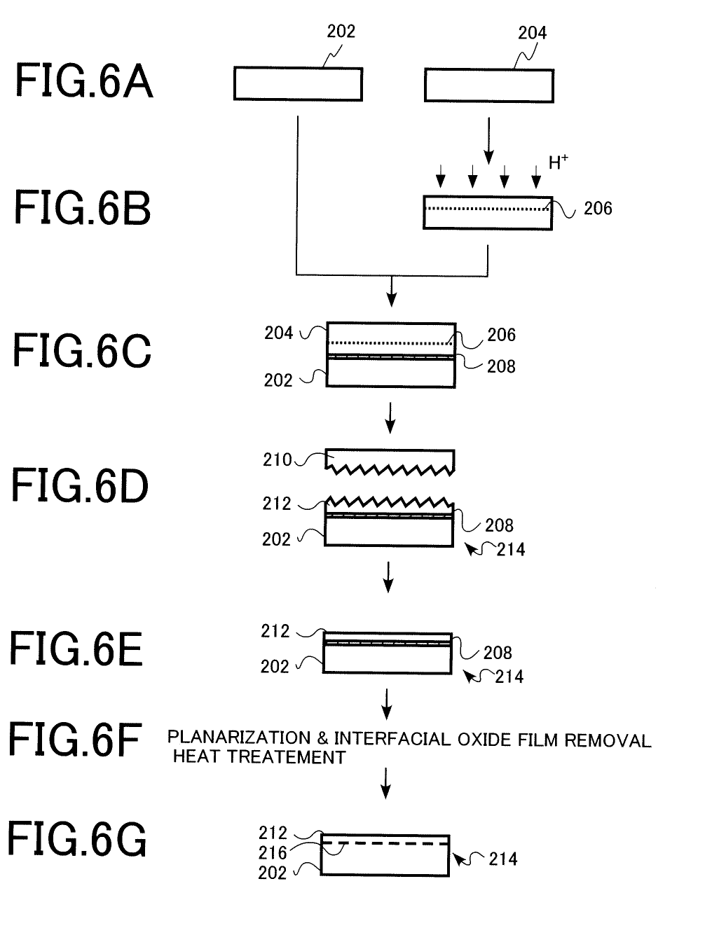

The manufacturing method of a semiconductor substrate in the present embodiment will be described more specifically below with reference to the diagram of a manufacturing process flow in FIG. 6. First, in a process shown in FIG. 6A, a semiconductor single crystal ingot in the crystal orientation {100} grown, for example, by the Czochralski method (CZ method) is sliced substantially in parallel to the {100} surface to fabricate a silicon wafer. Here, being substantially in parallel to the {100} surface means more specifically that the semiconductor single crystal ingot is sliced in such a way that the inclination (off angle) with respect to the {100} surface is 0 degree or more and 5 degrees or less. Subsequently, the silicon wafer undergoes, for example, RCA cleaning and then is mirror-polished. In this way, the base wafer (first silicon wafer) 202 whose surface has a predetermined inclination (off angle) with respect to the {100} surface is prepared.

Incidentally, the inclination with respect to the {100} surface is set to 0 degree or more and 5 degrees or less because, if this range is exceeded, an effect of increased mobility of carriers may not be sufficiently received by each of nMOSFET and pMOSFET. Also, if this range is exceeded and surface planarization heat treatment described later is added before bonding, an effect of improved planarization on the surface of a wafer cannot be expected because formation of a step structure in which a flat surface of the wafer surface becomes a crystal plane becomes difficult.

Next, as shown in FIG. 6A, the bond wafer (second silicon wafer) 204 is prepared by slicing the semiconductor single crystal ingot in the crystal orientation {110} grown, for example, by the Czochralski method (CZ method) at an inclination (off angle) of 0 degree or more and 0.12 degrees or less, or 5 degrees or more and 11 degrees or less, preferably 6 degrees or more and 9 degrees or less with respect to the {10} surface.

This is because, as described above, surface roughness after heat treatment of semiconductor substrates to be manufactured is reduced by selecting the inclination of 0 degree or more and 0.12 degrees or less, or 5 degrees or more and 11 degrees or less, and the surface roughness is further reduced by selecting the inclination of 6 degrees or more and 9 degrees or less. When the inclination is in the range of 6 degrees or more and 9 degrees or less, dependence of surface roughness after heat treatment on the inclination is small and stable. Thus, there is an advantage that wafer surface planarization after heat treatment is stabile even if the slicing angle varies in a process of slicing.

Here, when growing a single crystal by the CZ method, as is generally practiced, the {110} surface of a seed crystal may be matched to the horizontal plane for growing the single crystal. However, it is preferable that a single crystal be grown by tilting the {110} surface of the seed crystal in advance by 0 degree or more and 0.12 degrees or less, or 5 degrees or more and 11 degrees or less, preferably 6 degrees or more and 9 degrees or less, for example, 8 degrees with respect to the horizontal plane.

This is because, by growing the silicon single crystal ingot after the seed crystal being tilted in advance by an angle corresponding to a desired inclination, the silicon single crystal ingot will be sliced almost perpendicularly to the length direction of the silicon single crystal ingot in the slicing process. Therefore, slicing work will be made easier. Moreover, the volume of single crystal in the silicon single crystal ingot that will be unusable as a silicon wafer and thus discarded can be reduced by slicing the silicon single crystal ingot almost perpendicularly, realizing reduced manufacturing costs.

In the present embodiment, the azimuth in the direction of dip with respect to the {110} surface is not necessarily limited in the process of slicing a silicon single crystal ingot. However, it is preferable that the silicon single crystal ingot be sliced in such a way that the azimuth on the {110} surface of the direction of dip with respect to the {110} surface be in the range of +5 degrees with respect to the <100> direction, that is, the azimuth β shown in FIG. 2 be in the range of 0 degree±5 degrees. This is because a benefit of improved hole mobility will be received by pMOSFET formed on a silicon wafer for the semiconductor substrate manufactured in this manner. In addition, as described above, there is an advantage that a semiconductor substrate manufactured in this manner has no variations in hole mobility originating from variations in inclination when cutting out silicon wafers from an ingot by slicing.

Subsequently, the silicon wafer undergoes, for example, RCA cleaning and then is mirror-polished. In this way, the bond wafer (second silicon wafer) 204 whose surface has a predetermined inclination (off angle) with respect to the {110} surface is prepared.

Next, in a process shown in FIG. 6B, hydrogen ions or inert gas ions, here 3E16 to 1E17 atoms/cm² or so of hydrogen ions are injected onto one side of the bond wafer 204 to form a micro bubble layer (encapsulation layer) 206 in parallel to the wafer surface in an average penetration depth of ions.

Next, in a process shown in FIG. 6C, the hydrogen ion injected surface of the bond wafer 204 and the surface of the base wafer 202 are bonded together at normal atmospheric pressure or reduced pressure.

Cleaning such as RCA cleaning is performed before bonding to remove deposits on the wafer surface and also a natural oxide film (silicon oxide film) of about 1 to 2 nm in thickness is grown on each surface. In the process of bonding together, silicon wafers can be bonded without using an adhesive or the like, for example, by contacting surfaces of two silicon wafers in a clear atmosphere at normal temperature. However, it is difficult to bond two silicon wafers if there is not a sufficient amount of silicon oxide film at the interface.

In this process, the thickness of an interfacial oxide film 208 is made to be 10 nm or less. The interfacial oxide film 208 is adjusted by formation of a natural oxide film by cleansing before bonding and removal of the formed natural oxide film by dilute fluoric acid (HF) or the like. Here, the thickness of an interfacial oxide film 208 is made to be 10 nm or less because, if the thickness exceeds 10 nm, it becomes very difficult to completely remove the interfacial oxide film in heat treatment later. Next, bonding heat treatment is provided to the bonded silicon substrate at 200° C. for about 10 hours to increase bonding strength at the interface.

Next, in a process shown in FIG. 6D, the substrate is divided into a peeling wafer 210 and a silicon substrate 214 at the micro bubble layer (encapsulation layer) 206 as being a boundary. The silicon substrate 214 is a substrate obtained by bonding an upper silicon substrate layer 212, which is part of the bond wafer 204, and the base wafer 202. By providing heat treatment, for example, in an atmosphere of inert gas at about 450° C. or more in this process, the division into the peeling wafer 210 and the silicon substrate 214 occurs due to rearrangement of silicon atoms and aggregation of hydrogen bubbles. The bond wafer 204, which is the second silicon wafer, is made thinner by this division.

Improvement of planarization at the bonding interface after heat treatment becomes more pronounced as the base wafer 204 becomes thinner. Therefore, it is preferable that the second silicon wafer, which is a bond wafer, be made thinner to 1 μm or less, if possible, 200 nm or less.

Next, in a process shown in FIG. 6E, treatment to planarize the surface of the silicon substrate 214 is performed. This planarization treatment can be considered to be performed, for example, by surface polishing by a polishing apparatus, heat treatment in an atmosphere of a reducing gas or insert gas, or wet etching.

Next, in a process shown in FIG. 6F, the silicon substrate 214 is heat-treated, for example, in an atmosphere of a reducing gas, an inert gas, or a mixed gas of a reducing gas and an inert gas at a temperature of 900° C. or higher and 1350° C. or lower for a time of 30 minutes or more and 5 hours or less. This heat treatment is intended to perform planarization of the surface of the silicon substrate 214 and removal of the interfacial oxide film 208 in one process. This heat treatment is performed, for example, by using a vertical heat treating furnace with heating by a heater.

Here, a reducing gas, an inert gas, or a mixed gas of a reducing gas and an inert gas is used as an atmosphere for heat treatment because, if any other gas is used, atoms at the silicon wafer surface will not be reconstituted, making planarization of the silicon wafer surface difficult. Particularly, if an oxidizing gas mingles, reconstitution of atoms at the silicon surface becomes extremely difficult due to oxidization of the silicon wafer surface.

Also, heat treatment is provided at a temperature of 900° C. or higher and 1350° C. or lower for a time of 30 seconds or more and 2 hours or less because, if heat treatment is provided in the range of lower temperature or shorter time, it becomes difficult to realize planarization by heat treatment. If, on the other hand, heat treatment is provided in the range of higher temperature or longer time, metallic contamination of silicon wafers increases. Further, if heat treatment is provided in the range of higher temperature or longer time, the probability of occurrence of a slip to silicon wafers increases and also the life of members of a heat treatment apparatus decreases, making heat treatment unrealistic.

With the planarization/interfacial oxide film removal heat treatment, as shown in FIG. 6G, the silicon substrate 214 in which the upper silicon substrate layer 212 having the inclination (off angle) of 0 degree or more and 0.12 degrees or less, or 5 degrees or more and 11 degrees or less with respect to the crystal orientation {110} whose surface has been planarized and the base wafer 202 having mostly the crystal orientation {100} are bonded is formed. In the present embodiment, bonding heat treatment to increase bonding strength and this planarization/interfacial oxide film removal heat treatment are separate heat treatment. However, in view of simplification of the manufacturing process of the silicon substrate 214, the bonding heat treatment and planarization/interfacial oxide film removal heat treatment can be performed as single heat treatment.

Incidentally, the silicon single crystal ingot used here need not be necessarily a single crystal grown by the Czochralski method (CZ method) and, for example, may be a single crystal grown by the floating zone method (FZ method). Also, the heat treatment apparatus used by the manufacturing method in the present embodiment is not particularly limited and, for example, a batch-type vertical heat treating furnace or a single wafer RTP (Rapid Thermal Processing) apparatus may be used.

In the present embodiment, the so-called smart cut method using hydrogen ion injection is used to make a bond wafer thinner. However, the method for making the bond wafer thinner is not necessarily limited to the smart cut method and, for example, a method of physical surface grinding/polishing may be applied or any other publicly known method may be applied.

The present embodiment has been described by assuming that the semiconductor substrate is made of silicon (Si), but a similar operation effect can be gained by SixGe1−x (0≦x<1), which has a crystal structure basically similar to that of silicon. In addition, by using SixGe1−x (0≦x<1) as a material, mobility of carriers, particularly holes, which are carriers of pMOSFET, is enhanced. Thus, an effect that LSI formed on a semiconductor substrate achieves ever higher performance is gained.

According to the manufacturing method of a silicon substrate in the present embodiment described above, a manufacturing method of a silicon substrate formed by directly bonding silicon wafers having different crystal surface orientations, wherein characteristics of a semiconductor device formed on the surface are enhanced by improving surface flatness of the bonding interface and reducing surface roughness, can be provided.

The wafer surface on which a device is formed is planarized by the manufacturing method in the present embodiment. Here, the desirable RMS value for device formation cannot be necessarily determined uniquely in view of demanded device performance. However, it is generally preferable that the RMS value of about 0.2 nm or less be realized. High device performance can be realized by forming a device using a semiconductor substrate manufactured by the manufacturing method in the present embodiment and whose surface has a RMS value of 0.2 nm or less.

### Fifth Embodiment

A manufacturing method of a semiconductor substrate in the present embodiment is similar to that in the fourth embodiment except that the manufacturing method includes a process in which the bond wafer (second silicon wafer) 204 whose surface has the inclination (off angle) of 0 degree or more and 0.12 degrees or less, or 5 degrees or more and 11 degrees or less with respect to the {110} surface is heat-treated in an atmosphere of a reducing gas, an inert gas, or a mixed gas of a reducing gas and an inert gas at a temperature of 900° C. or higher and 1350° C. or lower for a time of 30 minutes or more and 5 hours or less before the process of bonding silicon wafers together and thus, a repetitional description thereof is omitted.

According to the manufacturing method in the present embodiment, surface flatness of the surface of the bond wafer (second silicon wafer) 204 is improved by heat treatment before bonding. Therefore, compared with the fourth embodiment, surface flatness of the bonding interface is improved still more to realize further enhancement of characteristics of semiconductor devices formed on the surface of a semiconductor substrate.

Moreover, it is preferable to add heat treatment before bonding not only to the bond wafer (second silicon wafer) 204, but also to the base wafer (first silicon wafer) 202 substantially having the {110} surface orientation. This is because surface flatness of the bonding interface can further be improved by planarizing the surface with addition of heat treatment before bonding to the base wafer 202 as well.

Examples of the present invention will be described below, but the present invention is not limited by these examples.

### Example 4

A silicon single crystal ingot measuring 200 mm (8 inches) in diameter and having the crystal surface orientation (100) was fabricated by the Czochralski method (CZ method). Then, the silicon single crystal ingot was sliced in parallel to the (100) surface in such a way that the off angle of the silicon wafer surface with respect to the (100) surface becomes about 0.2 degrees.

Next, a silicon single crystal ingot measuring 200 mm (8 inches) in diameter and having the crystal surface orientation (110) was fabricated by the Czochralski method (CZ method). The silicon single crystal ingot was grown and pulled up while the (110) surface of the seed crystal being tilted by 8 degrees with respect to the horizontal plane during elevation. The ingot is a p-type silicon single crystal with boron as impurities and having resistivity of 9 to 22 Ω·cm. The silicon single crystal ingot was sliced in such a way that the azimuth of the surface of a silicon wafer to be cut out on the (110) surface in the direction of dip with respect to the (110) surface matches the <100> direction, that is, the azimuth D shown in FIG. 2 is 0 degree.

Also, by slicing the silicon single crystal ingot at an inclination (off angle) in increments of 1 degree from 0 degree to 12 degrees with respect to the (110) surface while the inclination azimuth βbeing set to 0 degree, silicon wafers with different inclinations (off angles) indicated by the angle α in FIG. 2 were prepared. Next, silicon wafers obtained by slicing underwent RCA cleaning and then were mirror-polished. Subsequently, hydrogen ions were injected into the bond wafer under conditions of the acceleration voltage of 20 Kev, the current value of 4 mA, and the irradiation time of 200 seconds. Under these conditions, hydrogen ions are uniformly injected into the depth of about 200 nm from the surface. Under the above conditions, the dose amount is 5E16 atoms (ions)/cm².

Next, the hydrogen ion injection surface of a bond wafer 104 into which hydrogen ions had been injected after RCA cleaning and the base wafer 102 were piled up to bring them into close contact before being bonded together. The thickness of surface oxide film after RCA cleaning of each of the base wafer and bond wafer was about 2 nm. The two wafers were piled and brought into close contact by an automatic gluing machine at 100° C. and reduced pressure of 1E-6 Pa. Next, heat treatment was provided to the bonded silicon substrate at 200° C. for 10 hours to increase bonding strength at the gluing interface.

A bond wafer portion was divided from each sample by providing heat treatment in an atmosphere of argon gas at about 450° C. Accordingly, the thickness of the upper silicon substrate layer became about 200 nm. Subsequently, the surface of each sample was planarized by polishing using a surface polishing apparatus. Then, after planarization by polishing, planarization/interfacial oxide film removal heat treatment was performed in an atmosphere of argon gas at about 1200° C. for 1 hour.

Surface roughness of the above silicon wafers was evaluated in arbitrary 10 μm×10 μm measuring areas by means of AFM (Nano Scope IIIa). RMS (Root Mean Square) was used as an index of surface roughness. Also, whether there was an interfacial oxide film was checked by means of a cross section TEM (Transmission Electron Microscopy).

Like Example 1 described above, the surface roughness in the range where the inclination (off angle) α is 5 degrees or more and 11 degrees or less is satisfactory with a value equal to or less than that in the vicinity of 0 degree. Further, when the inclination (off angle) α is 6 degrees or more and 9 degrees or less, the surface roughness is more satisfactory with stabilizing surface roughness of about half that in the vicinity of 0 degree or less. Moreover, no interfacial oxide film was found after heat treatment.

Measurement of the silicon wafer sliced by aiming at the 0 degree using a high-performance X-ray diffractometer showed that the silicon wafer has an inclination of 0.45 degrees.

### Example 5

The same experiment as that in the Example 4 except that silicon wafers with different inclinations (off angles) indicated by the angle α in FIG. 2 were prepared by slicing at inclinations (off angles) in the range of 0 to 0.5 degrees with respect to the (110) surface was performed.

Like Example 3 as described above, the surface roughness is satisfactory with the RMS value of 0.2 nm or less when the inclination (off angle) α is in the range of 0.0 degree or more and 0.12 degrees or less. Moreover, no interfacial oxide film was found after heat treatment.

Embodiments of the present invention have been described with reference to concrete examples. Though descriptions of parts that were not directly necessary to describe the present invention such as a semiconductor substrate and a manufacturing method of a semiconductor substrate were omitted when describing the embodiments, necessary components related to the semiconductor substrate or the manufacturing method of a semiconductor substrate can appropriately be selected and used. In addition, all semiconductor substrates and manufacturing methods thereof that have components of the present invention and whose design can be appropriately modified by a person skilled in the art are included in the scope of the present invention.

What is claimed is:

1. A semiconductor substrate, wherein a surface of the semiconductor substrate has an inclination (off angle) of 0 degree or more and 0.12 degrees or less, or 5 degrees or more and 11 degrees or less with respect to a {110} surface.

2. The semiconductor substrate according to claim 1, wherein the surface has the inclination (off angle) of 6 degree or more and 9 degrees or less with respect to the {110} surface.

3. The semiconductor substrate according to claim 1, wherein an azimuth when a direction of dip of the surface with respect to the {110} surface is projected onto the {110} surface is in a range of ±26 degrees with respect to a <100> direction.

4. The semiconductor substrate according to claim 1, wherein an azimuth when a direction of dip of the surface with respect to the {110} surface is projected onto the {110} surface is in a range of ±5 degrees with respect to a <100> direction.

5. The semiconductor substrate according to claim 1, wherein an azimuth when a direction of dip of the surface with respect to the {110} surface is projected onto the {110} surface is in a range of ±2 degrees with respect to a <100> direction.

6. The semiconductor substrate according to claim 1, wherein the semiconductor substrate is formed of SixGe1−x (0≦x<1).

7. A method of manufacturing a semiconductor substrate, wherein a semiconductor single crystal ingot is sliced at an inclination (off angle) of 0 degree or more and 0.12 degrees or less, or 5 degrees or more and 11 degrees or less with respect to a {110} surface.

8. The method according to claim 7, wherein the semiconductor substrate obtained by the slicing is heat-treated in an atmosphere of a reducing gas, an inert gas, or a mixed gas of a reducing gas and an inert gas at a temperature of 900° C. or higher and 1350° C. or lower for a time of 30 minutes or more and 5 hours or less.

9. The method according to claim 7, wherein the slicing is performed in such a way that an azimuth when a direction of dip of a surface of the semiconductor substrate with respect to the {110} surface is projected onto the {110} surface is in a range of ±26 degrees with respect to a <100> direction.

10. The method according to claim 7, wherein the slicing is performed in such a way that an azimuth when a direction of dip of a surface of the semiconductor substrate with respect to the {110} surface is projected onto the {110} surface is in a range of ±5 degrees with respect to a <100> direction.

11. The method according to claim 7, wherein the slicing is performed in such a way that an azimuth when a direction of dip of a surface of the semiconductor substrate with respect to the {110} surface is projected onto the {110} surface is in a range of +2 degrees with respect to a <100> direction.

12. A semiconductor substrate formed by a first semiconductor wafer and a second semiconductor wafer being directly bonded, comprising:
a surface of one semiconductor wafer of the first semiconductor wafer and the second semiconductor wafer substantially has a {100} surface orientation; and
the surface of another semiconductor wafer has an inclination (off angle) of 0 degree or more and 0.12 degrees or less, or 5 degrees or more and 11 degrees or less with respect to a {110} surface.

13. The semiconductor substrate according to claim 12, wherein the surface of the other semiconductor wafer has the inclination (off angle) of 6 degrees or more and 9 degrees or less with respect to the {110} surface.

14. The semiconductor substrate according to claim 12, wherein an azimuth when a direction of dip of the surface of the other semiconductor wafer with respect to the {110} surface is projected onto the {110} surface is in a range of ±5 degrees with respect to a <100> direction.

15. The semiconductor substrate according to claim 12, wherein the other semiconductor wafer is thicker than the one semiconductor wafer.

16. A method of manufacturing a semiconductor substrate by bonding a first semiconductor wafer and a second semiconductor wafer; comprising:
preparing the first semiconductor wafer by slicing a semiconductor single crystal ingot substantially horizontally with respect to a {100} surface; and
preparing the second semiconductor wafer by slicing the semiconductor single crystal ingot at an inclination (off angle) of 0 degree or more and 0.12 degrees or less, or 5 degrees or more and 11 degrees or less with respect to a {110} surface.

17. The method according to claim 16, wherein the second semiconductor wafer is prepared by slicing the semiconductor single crystal ingot at the inclination (off angle) of 6 degrees or more and 9 degrees or less with respect to the {110} surface.

18. The method according to claim 16, wherein slicing is performed in such a way that an azimuth when a direction of dip of a surface of the second semiconductor wafer with respect to the {110} surface is projected onto the {110} surface is in a range of ±5 degrees with respect to a <100> direction.

19. The method according to claim 16; further comprising:
thinning the second semiconductor wafer portion after bonding the first semiconductor wafer and the second semiconductor wafer together, and
heating a semiconductor wafer bonded in an atmosphere of a reducing gas, an inert gas, or a mixed gas of a reducing gas and an inert gas at a temperature of 900° C. or higher and 1350° C. or lower for a time of 30 minutes or more and 5 hours or less.

20. The method according to claim 16, further comprising wherein,
heating the second semiconductor wafer before the bonding is performed in an atmosphere of a reducing gas, an inert gas, or a mixed gas of a reducing gas and an inert gas at a temperature of 900° C. or higher and 1350° C. or lower for a time of 30 minutes or more and 5 hours or less.
